(19) United States
(12) Patent Application Publication
(10) Pub. No.: US 2013/0258776 A1
(43) Pub. Date: Oct. 3, 2013

(54) NON-VOLATILE SEMICONDUCTOR MEMORY DEVICE AND METHOD OF READING DATA THEREFROM

(71) Applicant: Yasushi NAGADOMI, Yokohama-shi (JP)

(72) Inventor: Yasushi NAGADOMI, Yokohama-shi (JP)

(73) Assignee: KABUSHIKI KAISHA TOSHIBA, Tokyo (JP)

(21) Appl. No.: 13/597,647

(22) Filed: Aug. 29, 2012

(30) Foreign Application Priority Data
Mar. 29, 2012 (JP) P2012-075408

(51) Int. Cl. G11C 16/26

(52) U.S. Cl. CPC G11C 16/26
USPC 365/185.11; 365/185.2; 365/185.17

(57) ABSTRACT

A non-volatile semiconductor memory device according to an aspect includes a memory cell array and a control circuit. The memory cell array includes a plurality of memory cells, and stores initial setting data in each of a plurality of storage areas. The control circuit reads the initial setting data from the storage areas. The control circuit is configured to read, when it detects an error in the initial setting data read from one of the storage areas, initial setting data from another storage area.

### CROSS-REFERENCE TO RELATED APPLICATIONS

This application is based upon and claims the benefit of priority from the prior Japanese Patent Application No. 2012-075408, filed on Mar. 29, 2012, the entire contents of which are incorporated herein by reference.

### FIELD

The embodiments relate to a non-volatile semiconductor memory device and a method of reading data therefrom.

### BACKGROUND

In recent years, for a more integrated memory cell, a number of semiconductor memory devices (stacked non-volatile semiconductor memory devices) including three-dimensionally arranged memory cells have been proposed. Even in the stacked non-volatile semiconductor memory devices, initial setting is necessary on power-up for various types of operations performed for a memory cell.

### BRIEF DESCRIPTION OF THE DRAWINGS

FIG. 1 is a block diagram of a non-volatile memory system 100 according to a first embodiment.

FIG. 2 is a block diagram of a memory chip 200 according to the first embodiment.

FIG. 3 is a circuit diagram of a memory cell array 201 according to the first embodiment.

FIG. 4 is a schematic perspective view of the memory cell array 201 according to the first embodiment.

FIG. 5 is a cross-sectional view of the memory cell array 201 according to the first embodiment.

FIG. 6 shows storage areas of initial setting data A according to the first embodiment.

FIG. 7 is a read operation of the initial setting data A according to the first embodiment.

FIG. 8 is a read operation of the initial setting data A according to a second embodiment.

FIG. 9 shows storage areas (WL and String) from which the initial setting data A is read and a scheme (Mode) whereby the initial setting data A is read, with respect to the number of times of reading the initial setting data A, according to the second embodiment.

FIG. 10 is a read operation of the initial setting data A according to a third embodiment.

FIG. 11 shows storage areas of the initial setting data A and address B according to a fourth embodiment.

FIG. 12 is a flowchart of a read operation of the initial setting data A according to the fourth embodiment.

FIG. 13 shows addresses B(2) to B(n) of a memory chip 200(1) according to a fifth embodiment.

FIG. 14 is a flowchart of a read operation of the initial setting data A according to the fifth embodiment.

FIG. 15 shows storage areas of the initial setting data A according to another embodiment.

FIG. 16 shows storage areas of the initial setting data A according to another embodiment.

### DETAILED DESCRIPTION

A non-volatile semiconductor memory device according to an aspect has a memory cell array and a control circuit. The memory cell array comprises a plurality of memory cells, and stores initial setting data in each of a plurality of storage areas. The control circuit reads initial setting data from the storage areas. The control circuit is configured to read, when an error is detected in the initial setting data read from one of the storage areas, the initial setting data from another storage area.

Referring to the drawings, non-volatile semiconductor memory devices according to embodiments will be described below.

### First Embodiment

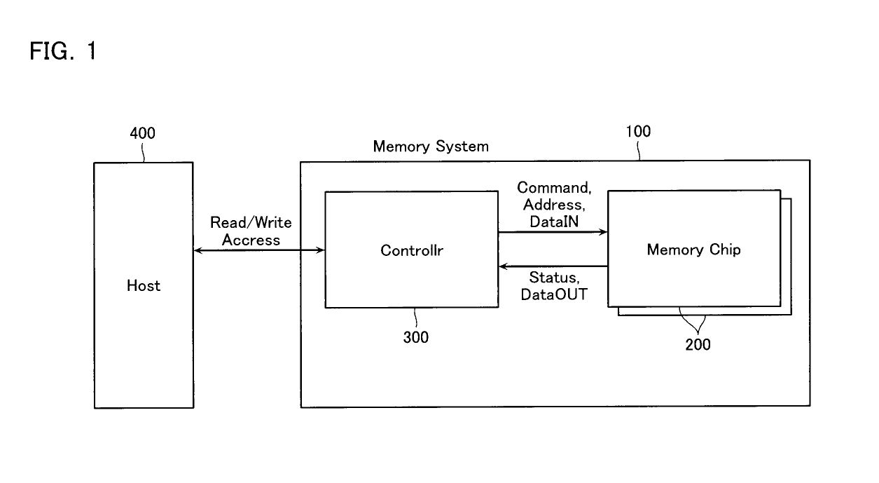

First, referring to FIG. 1, the entire configuration of a non-volatile memory system according to a first embodiment will be described. FIG. 1 is a block diagram of a non-volatile memory system 100 according to the first embodiment.

With reference to FIG. 1, the non-volatile memory system 100 includes a plurality of NAND memory chips 200 (non-volatile semiconductor memory devices), and a controller 300 for controlling the memory chips 200. The controller 300 operates in response to a control signal from an external host computer 400. The controller 300 accesses the memory chips 200 and instructs them to perform data read, data write, data erase, or the like.

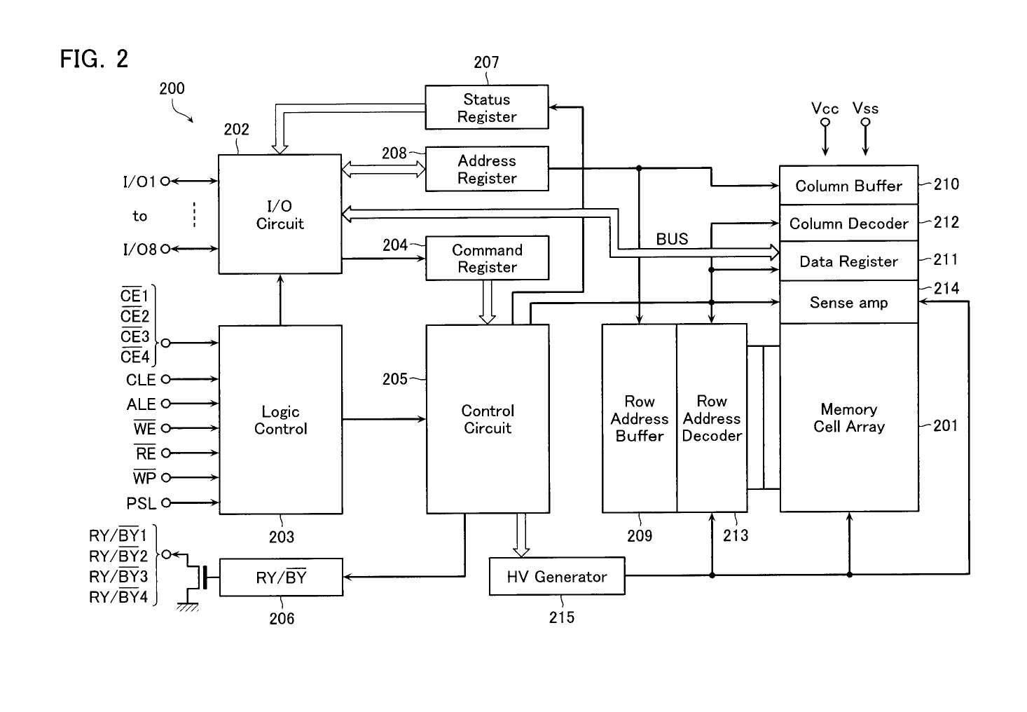

Referring now to FIG. 2, a specific configuration of each memory chip 200 will be described. With reference to FIG. 2, each memory chip 200 includes a memory cell array 201 for storing data in a non-volatile manner, and various circuits 202 to 215 for controlling the memory cell array 201.

The input/output circuit 202 inputs/outputs a command, an address, and data via an input/output pad I/O. The input/output circuit 202 is connected to a command register 204, a status register 207, an address register 208, and a data register 211, as described below.

The logic control circuit 203 receives chip enable signals /CE1 to /CE4, a command latch enable signal CLE, an address latch enable signal ALE, a write enable signal /WE, a read enable signal /RE, a write protect signal /WP, a selection control signal PSL, and other control signals. The logic control circuit 203 controls the memory cell array 201 according to those signals. The logic control circuit 203 is connected to the input/output circuit 202 and a control circuit 205 as described below. The command register 204 decodes a command that is input to the input/output circuit 202. The command register 204 is connected to the control circuit 205 as described below.

The control circuit 205 performs the data transfer control and the sequence control of the data write/erase/read. The control circuit 205 is connected to status registers 206 and 207, a data register 211, a column decoder 212, a sense amplifier 214, and a high voltage generation circuit 215, as described below.

The status register 206 (which shows RY//BY in FIG. 2) outputs a signal to the Ready/Busy terminal, the signal showing the Ready/Busy state of the memory chip 200. The status register 207 receives a signal from the control circuit 205, the signal showing the state (such as Pass/Fail and Ready/Busy) of the memory chip 200, and outputs the signal to the host computer 400 via the input/output circuit 202.

A row address buffer 209 and a column address buffer 210 receive address data via the address register 208 and transfer it. The row address buffer 209 is connected to a row decoder 213 as described below. The column address buffer 210 is connected to a column decoder 212 as described below.

The data register 211 has functions of temporarily holding write data to the memory cell array 201 and of temporarily holding read data from the memory cell array 201. The write data is transferred to the data register 211 via the input/output circuit 202 and a data bus BUS.

According to address data supplied from the row address buffer 209 and the memory cell array 201, the column decoder 212 and the row decoder 213 perform a control of selecting a word-line WL, a bit-line BL, a source-line SL, and the like of the memory cell array 201 as described below, and applying desired voltages to them. The sense amplifier 214 senses and amplifies the voltage of the bit-line BL, and reads data from the memory cell array 201.

The high voltage generation circuit 215 generates the desired high voltage for each operation mode. The high voltage generation circuit 215 generates a predetermined high voltage according to an instruction provided from the control circuit 205. The high voltage generation circuit 215 is connected to the memory cell array 201, the row decoder 213, and the sense amplifier 214.

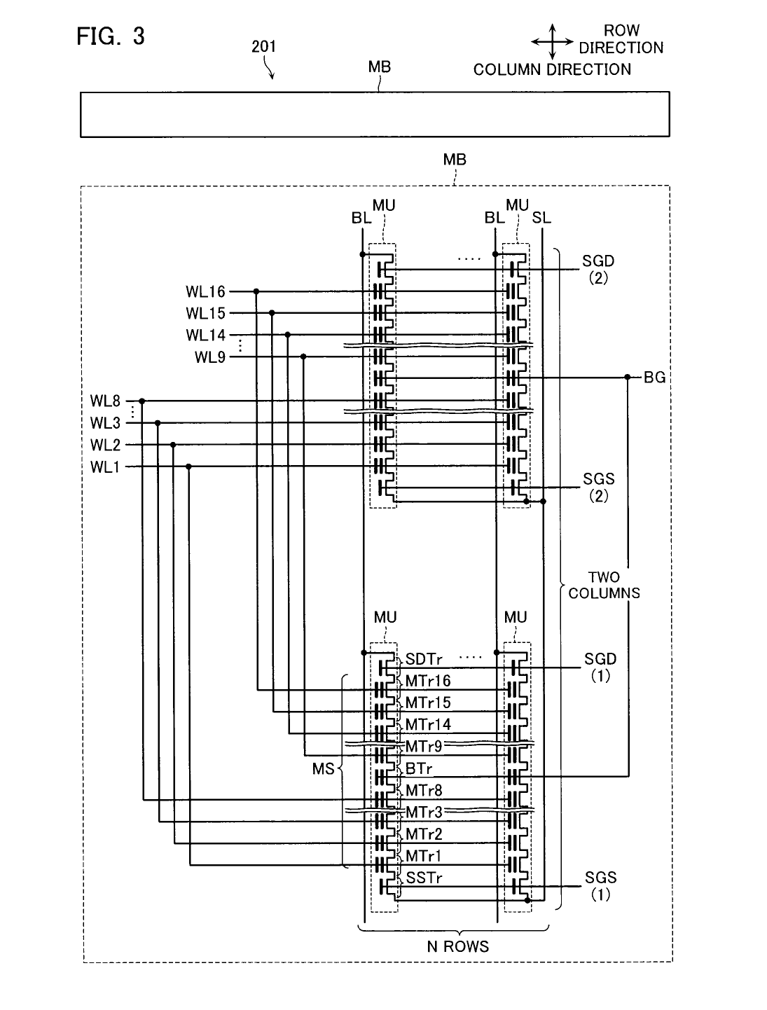

Referring now to FIG. 3, the circuitry of the memory cell array 201 will be specifically described.

With reference to FIG. 3, the memory cell array 201 includes a plurality of memory blocks MB. Each memory block MB includes a three-dimensional array of a plurality of memory transistors MTr (memory cells) each storing data in a non-volatile manner. Each memory block MB provides a minimum erase unit that may be collectively erased when the data erase operation is performed.

With reference to FIG. 3, the memory block MB includes a plurality of bit-lines BL, a source-line SL, and a plurality of memory units MU connected to the bit-lines BL and the source-line SL.

Each memory block MB includes memory units MU arranged in a matrix of n-rows and two columns. Note that the n-rows and two columns are merely an example, and the embodiment is not limited thereto.

First ends of the memory units MU are connected to the bit-lines BL. Second ends of the memory units MU are connected to the source-line SL. The bit-lines BL are arranged in the row direction at a predetermined pitch and extend in the column direction.

Each memory unit MU includes a memory string MS, a source-side select transistor SSTr, and a drain-side select transistor SDTr.

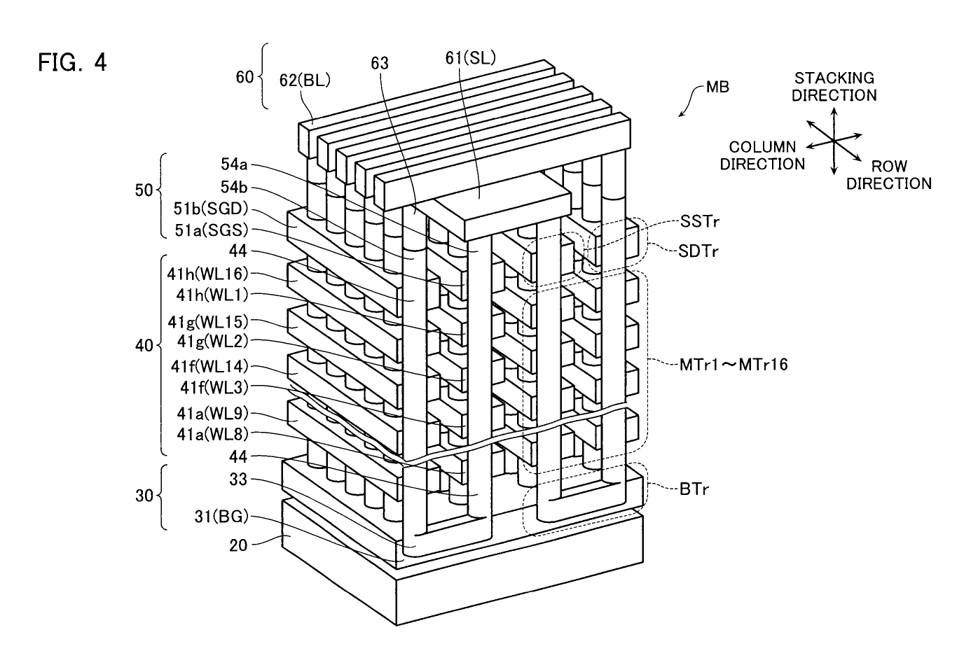

With reference to FIG. 3, the memory string MS includes memory transistors MTr1 to MTr16 (memory cells) and a back gate transistor BTr, which are connected in series. The memory transistors MTr1 to MTr8 are connected together in series. The memory transistors MTr9 to MTr16 are also connected together in series. The back gate transistor BTr is connected between the memory transistor MTr8 and the memory transistor MTr9. Note that the memory transistors MTr1 to MTr16 are three-dimensionally arranged in the row direction, the column direction, and the stacking direction (a direction substantially perpendicular to the substrate), as shown in FIG. 4 below. Note that FIG. 3 is an example, and the number of memory transistors in the memory string MS is not limited to 16 and may be more or less than 16.

The memory transistors MTr1 to MTr16 accumulate charge in their charge accumulation layers to hold data. The back gate transistor BTr is rendered conductive at least when the memory string MS is selected as the operation target.

In each memory block MB, the gates of the memory transistors MTr1 to MTr16 arranged in n-rows and two columns are commonly connected to the respective word-lines WL1 to WL16. The gates of the back gate transistors BTr arranged in n-rows and two columns are commonly connected to one back gate line BG.

The source-side select transistor SSTr has a drain connected to the source of the memory string MS. The source-side select transistor SSTr has a source connected to the source-line SL. In each memory block MB, the gates of the n source-side select transistors SSTr arranged in the row direction are commonly connected to one source-side select gate line SGS (1) or SGS (2). Note that the source-side select gate lines SGS (1) and SGS (2) may hereinafter be collectively referred to as a source-side select gate line SGS without distinction.

The drain-side select transistor SDTr has a source connected to the drain of the memory string MS. The drain-side select transistor SDTr has a drain connected to one of the bit-lines BL. In each memory block MB, the gates of the n drain-side select transistors SDTr arranged in the row direction are commonly connected to one drain-side select gate line SGD(1) or SGD(2). Note that the drain-side select gate lines SGD(1) and SGD(2) may hereinafter be collectively referred to as a drain-side select gate line SGD without distinction.

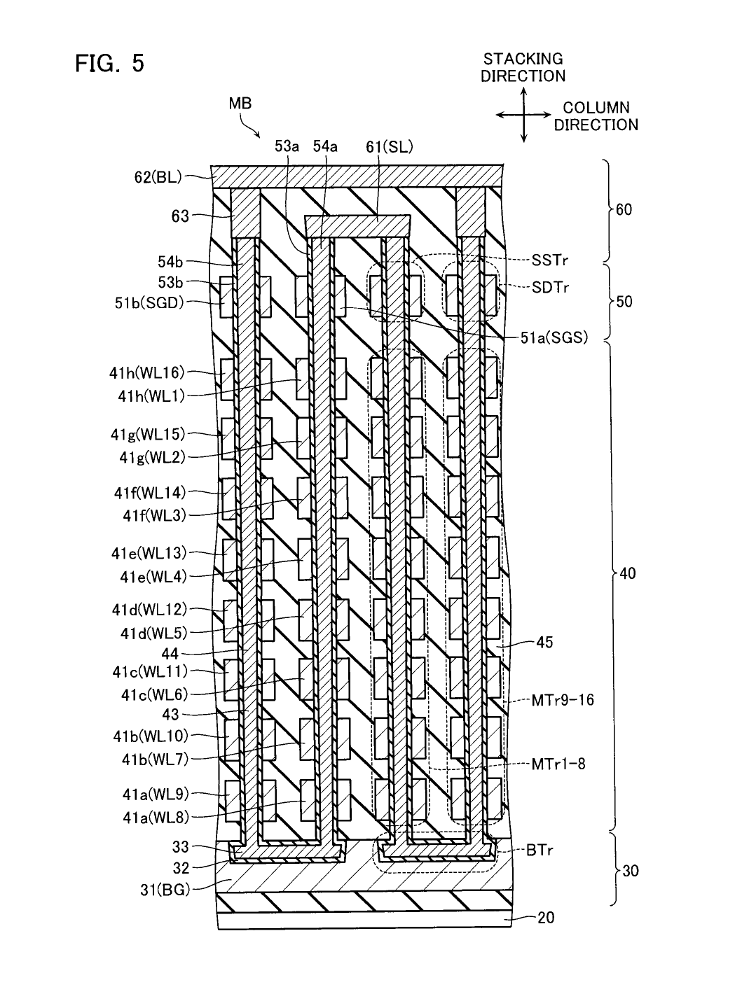

Referring now to FIG. 4 and FIG. 5, the stacked structure of the memory block MB will be described. With reference to FIG. 4 and FIG. 5, the memory block MB includes a back gate layer 30, a memory layer 40, a select transistor layer 50, and a wiring layer 60, which are sequentially stacked on a substrate 20. The back gate layer 30 functions as the back gate transistors BTr. The memory layer 40 functions as the memory transistors MTr1 to MTr16. The select transistor layer 50 functions as the drain-side select transistor SDTr and the source-side select transistor SSTr. The wiring layer 60 functions as the source-line SL and the bit-line BL.

With reference to FIG. 4 and FIG. 5, the back gate layer 30 includes a back gate conductive layer 31. The back gate conductive layer 31 functions as the back gate line BG and as the gates of the back gate transistors BTr. The back gate conductive layer 31 extends two-dimensionally like a plate in the row and column directions parallel to the substrate 20. The back gate conductive layer 31 is made of, for example, polysilicon (poly-Si).

With reference to FIG. 5, the back gate layer 30 includes a back gate insulating layer 32 and a back gate semiconductor layer 33.

The back gate insulating layer 32 is adapted to be capable of accumulating charge. The back gate insulating layer 32 is provided between the back gate semiconductor layer 33 and the back gate conductive layer 31. The back gate insulating layer 32 is formed in a stacked structure of, for example, silicon dioxide (SiO₂), silicon nitride (SiN), and silicon dioxide (SiO₂).

The back gate semiconductor layer 33 functions as the body (channel) of the back gate transistor BTr. The back gate semiconductor layer 33 is formed as trimming the back gate conductive layer 31. The back gate semiconductor layer 33 is made of, for example, polysilicon (poly-Si).

With reference to FIG. 4 and FIG. 5, the memory layer 40 is formed in a layer above the back gate layer 30. The memory layer 40 includes eight word-line conductive layers 41a to 41h. The word-line conductive layer 41a functions as the word-line WL8 and as the gate of the memory transistor MTr8. The word-line conductive layer 41a also functions as the word-line WL9 and as the gate of the memory transistor MTr9. Likewise, the word-line conductive layers 41b to 41h function as the respective word-lines WL1 to WL7 and as the respective gates of the memory transistors MTr1 to MTr7. The word-line conductive layers 41b to 41h also function as the respective word-lines WL10 to WL16 and as the respective gates of the memory transistors MTr10 to MTr16.

The word-line conductive layers 41a to 41d are stacked with an interlayer insulating layer 45 disposed therebetween. The word-line conductive layers 41a to 41h extend in the row direction (a direction perpendicular the plane of FIG. 5) as the longitudinal direction. The word-line conductive layers 41a to 41h are made of, for example, polysilicon (poly-Si).

With reference to FIG. 4 and FIG. 5, the memory layer 40 includes a memory gate insulating layer 43 and a memory columnar semiconductor layer 44.

The memory gate insulating layer 43 is adapted to be capable of accumulating charge. The memory gate insulating layer 43 is provided between the memory columnar semiconductor layer 44 and the word-line conductive layers 41a to 41h. The memory gate insulating layer 43 is formed in a stacked structure of, for example, silicon dioxide (SiO₂), silicon nitride (SiN), and silicon dioxide (SiO₂).

The memory columnar semiconductor layer 44 functions as the bodies (channels) of the memory transistors MTr1 to MTr16. The memory columnar semiconductor layer 44 passes through the word-line conductive layers 41a to 41h and the interlayer insulating layers 45, and extends in a direction perpendicular to the substrate 20. A pair of memory columnar semiconductor layers 44 are formed as aligning with the vicinity of the end portion of one back gate semiconductor layer 33 in the column direction. The memory columnar semiconductor layer 44 is formed of, for example, polysilicon (poly-Si).

In the above back gate layer 30 and memory layer 40, the pair of memory columnar semiconductor layers 44 and the back gate semiconductor layer 33 joining the lower ends thereof together function as the body (channel) of the memory string MS and are formed in a U shape when viewed in the row direction.

The above back gate layer 30 has, in other words, a configuration in which the back gate conductive layer 31 surrounds the side surface and bottom surface of the back gate semiconductor layer 33 via the memory gate insulating layer 32. Further, the above memory layer 40 has, in other words, a configuration in which the word-line conductive layers 41a to 41h surround the side surface of the columnar semiconductor layer 44 via the memory gate insulating layer 43.

With reference to FIG. 4 and FIG. 5, the select transistor layer 50 includes a source-side conductive layer 51a and a drain-side conductive layer 51b. The source-side conductive layer 51a functions as the source-side select gate line SGS and as the gate of the source-side select transistor SSTr. The drain-side conductive layer 51b functions as the drain-side select gate line SGD and as the gate of the drain-side select transistor SDTr.

The source-side conductive layer 51a is formed in a layer above the one of the pair of memory columnar semiconductor layers 44. The drain-side conductive layer 51b is formed in the same layer as the source-side conductive layer 51a. The drain-side conductive layer 51b is also formed in a layer above the other one of the pair of memory columnar semiconductor layers 44. More than one source-side conductive layer 51a and more than one drain-side conductive layer 51b are formed to be arranged in the column direction at a predetermined pitch and extend in the row direction. The source-side conductive layer 51a and drain-side conductive layer 51b are made of, for example, polysilicon (poly-Si).

With reference to FIG. 4 and FIG. 5, the select transistor layer 50 includes a source-side gate insulating layer 53a, a source-side columnar semiconductor layer 54a, a drain-side gate insulating layer 53b, and a drain-side column semiconductor layer 54b. The source-side columnar semiconductor layer 54a functions as the body (channel) of the source-side select transistor SSTr. The drain-side columnar semiconductor layer 54b functions as the body (channel) of the drain-side select transistor SDTr.

The source-side gate insulating layer 53a is provided between the source-side conductive layer 51a and the source-side columnar semiconductor layer 54a. The source-side gate insulating layer 53a is made of silicon dioxide (SiO₂).

The source-side columnar semiconductor layer 54a passes through the source-side conductive layer 51a and extends in a direction perpendicular to the substrate 20. The source-side columnar semiconductor layer 54a is connected to the side surface of the source-side gate insulating layer 53a and to the top surface of one of the pair of memory columnar semiconductor layers 44. The source-side columnar semiconductor layer 54a is made of, for example, polysilicon (poly-Si).

The drain-side gate insulating layer 53b is provided between the drain-side conductive layer 51b and the drain-side columnar semiconductor layer 54b. The drain-side gate insulating layer 53b is made of silicon dioxide (SiO₂).

The drain-side columnar semiconductor layer 54b passes through the drain-side conductive layer 51b, and extends in a direction perpendicular to the substrate 20. The drain-side columnar semiconductor layer 54b is connected to the side surface of the drain-side gate insulating layer 53b and to the top surface of the other one of the pair of memory columnar semiconductor layers 44. The drain-side columnar semiconductor layer 54b is made of, for example, polysilicon (poly-Si).

The wiring layer 60 includes a source-line layer 61, a bit-line layer 62, and a plug layer 63. The source-line layer 61 functions as the source-line SL. The bit-line layer 62 functions as the bit-lines BL.

The source-line layer 61 is in contact with the top surface of the source-side columnar semiconductor layer 54a and extends in the row direction. The bit-line layer 62 is in contact with the top surface of the drain-side columnar semiconductor layer 54b via the plug layer 63 and extends in the column direction. The source-line layer 61, the bit-line layer 62, and the plug layer 63 are made of metal such as tungsten.

A description is now given of the read operation of the initial setting data according to the first embodiment. Here, the initial setting data (initial setting parameter) is read (power on read) immediately after the power-up of the memory system 100. The initial setting data includes various types of parameter information necessary for the operation of the memory cell array 201. The initial setting data is used in the initial setting of the operation for the memory cell array 201. For example, if the initial setting data is read only once, an error in the initial setting data makes it uncertain that the memory cell array 201 operates correctly. Therefore, in this embodiment, if the initial setting data read from a storage area includes an error, the initial setting data is read again from another storage area, as described below.

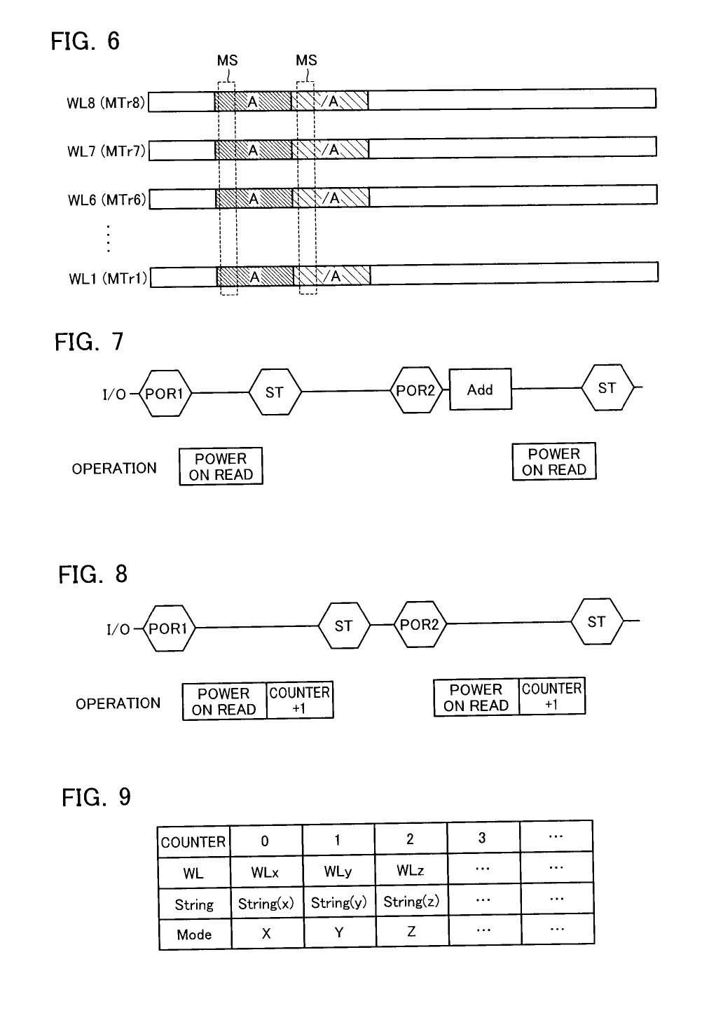

First, referring to FIG. 6, storage areas of the initial setting data A will be described. With reference to FIG. 6, a plurality of initial setting data sets A are stored in a plurality of memory transistors MTr1 to MTr8, as storage areas, arranged along the word-lines WL1 to WL8, respectively. Further, along with the initial setting data A, inverted data /A of the initial setting data A is stored in the memory transistors MTr1 to MTr8 arranged along the word-lines WL1 to WL8, respectively. In reading the initial setting data A, the inverted data /A is used to sense an error in the initial setting data A. For example, an error in the initial setting data A is generated by charge (electron, hole) recombination between the adjacent memory transistors MTr.

Further, with reference to FIG. 6, in the memory string MS that stores a portion of the initial setting data A or the inverted data /A, the memory transistors MTr1 to MTr8 hold the same data (1 or 0). Charge recombination between the adjacent memory transistors MTr may thus be suppressed.

Referring now to FIG. 7, the read operation of the initial setting data A will be specifically described. FIG. 7 shows an example where an error exists in the initially read initial setting data A and thus the initial setting data A is read again. Note that although the example in FIG. 7 only shows two readings of the initial setting data A, this embodiment is not limited thereto and may be applied to three or more readings of the initial setting data A.

With reference to FIG. 7, the control circuit 205 receives a read command POR1. FIG. 7 shows an example where the read command POR1 is a command to direct the control circuit 205 to read the initial setting data A from the memory transistors MTr8 arranged along the word-line WL8. Thus, the control circuit 205 reads, when receiving the read command POR1, the initial setting data A from the memory transistors MTr8 (power on read).

After the above read operation of the initial setting data, the control circuit 205 receives a status command ST. Here, the status command ST is a command to direct the control circuit 205 to report whether an error is sensed in the initial setting data A in the read operation of the initial setting data A. Thus, the control circuit 205 reports, when receiving the status command ST, whether an error is sensed in the initial setting data A. FIG. 7 shows an example where it is reported that an error exists in the initial setting data A. Then, the control circuit 205 receives a read command POR2 and an address Add. FIG. 7 shows an example where the read command POR2 is a command to direct the control circuit 205 to read the initial setting data A from the storage area (memory transistor) specified by the address Add. The address Add includes a predetermined number. For example, when the address Add is the number “0,” the memory transistors MTr8 arranged along the word-line WL8 are specified, while when the address Add is the number “1,” the memory transistors MTr7 arranged along the word-line WL7 are specified. Therefore, the control circuit 205 reads, when receiving the read command POR2 and the address Add, the initial setting data A from the storage area (memory transistor) specified by the address Add (power on read). For example, the read command POR2 and the address Add cause the control circuit 205 to read the initial setting data A from the memory transistors MTr7 arranged along the word-line WL7. Then, the control circuit 205 receives the status command ST again.

As described above, in this embodiment, the control circuit 205 reads, when an error is found in the initial setting data A stored in the memory transistors MTr8 arranged along the word-line WL8, the initial setting data A stored in the memory transistors MTr7 arranged along the word-line WL7. Thus, this embodiment may ensure that the accurate initial setting data A is read, thereby improving the operational reliability.

### Second Embodiment

A non-volatile memory system according to a second embodiment will be described. The configuration of the second embodiment is similar to that of the first embodiment and thus its description is omitted here. As described below, the read operation of the initial setting data A in the second embodiment is different from that in the first embodiment.

Referring to FIG. 8, the read operation of the initial setting data A will be specifically described. FIG. 8 shows an example where an error exists in the initially read initial setting data A and thus the initial setting data A is read again. Note that although the example in FIG. 8 only shows two readings of the initial setting data A, this embodiment is not limited thereto and may be applied to three or more readings of the initial setting data A.

With reference to FIG. 8, like the first embodiment, the second embodiment receives the read commands POR1 and POR2 and reads the initial setting data A. Note that in the second embodiment, the control circuit 205 counts, after reading the initial setting data A, the number of times the command is received, i.e., the number of times of reading the initial setting data A (counter +1). Depending on the number of times of reading the initial setting data A, the control circuit 205 changes, as shown in FIG. 9, the storage areas (WL and String) from which the initial setting data A is read and the scheme (Mode) whereby the initial setting data is read. Here, the read scheme includes, for example, a first read scheme and a second read scheme, as described below. In the first read scheme, data of the memory transistors MTr in the memory units MU connected to the even-numbered bit-lines BL is read at the same time as data of the memory transistors MTr in the memory units MU connected to the odd-numbered bit-lines BL. In the second read scheme, after data of the memory transistors MTr in the memory units MU connected to the odd-numbered bit-lines BL is read, data of the memory transistors MTr in the memory units MU connected to the even-numbered bit-lines BL is read.

With the above configuration, the second embodiment may exert an advantage similar to that in the first embodiment. Additionally, it is not necessary for the control circuit 205 in the second embodiment to receive the address Add unlike the first embodiment.

### Third Embodiment

A non-volatile memory system according to a third embodiment will be described. The configuration of the third embodiment is similar to that of the first embodiment and thus its description is omitted here. As described below, the read operation of the initial setting data A in the third embodiment is different from that in the first embodiment.

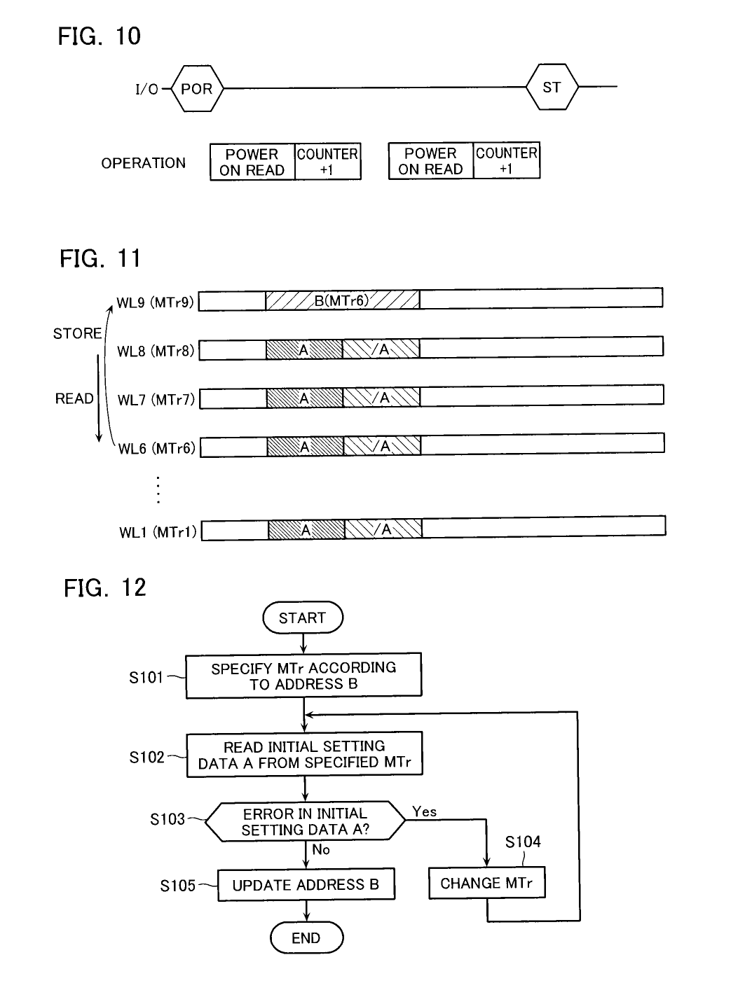

Referring to FIG. 10, the read operation of the initial setting data A will be specifically described. FIG. 10 shows an example where an error exists in the initially read initial setting data A and thus the initial setting data A is read again. Note that although the example in FIG. 10 only shows two readings of the initial setting data A, this embodiment is not limited thereto and may be applied to three or more readings of the initial setting data A.

With reference to FIG. 10, like the second embodiment, the third embodiment reads the initial setting data A (power on read), and counts the number of times of reading the initial setting data A (counter +1). Note that in the third embodiment, in response to one read command POR, the control circuit 205 reads the initial setting data A from a different storage area (memory transistor) every time an error is detected in the initial setting data A. FIG. 10 shows an example where two readings of the initial setting data A are performed in response to one read command POR.

With the above configuration, the third embodiment may exert an advantage similar to that in the first embodiment. Additionally, it is not necessary for the control circuit 205 in the third embodiment to receive the commands POR1 and POR2 every time the initial setting data A is read unlike the first and second embodiments.

### Fourth Embodiment

A non-volatile memory system according to a fourth embodiment will be described. The configuration of the fourth embodiment is similar to that of the first embodiment and thus its description is omitted here. As described below, the read operation of the initial setting data A in the fourth embodiment is different from that in the first embodiment.

In the fourth embodiment, the initial setting data A is read in the order of the memory transistors MTr8, MTr7, MTr6, . . . . If, however, the read operation is started from the memory transistor MTr8 every time the initial setting data A is read, a large number of readings are performed.

In the fourth embodiment, therefore, as shown in FIG. 11, an address B is stored in the memory transistors MTr9, as storage areas, arranged along the word-line WL9. The address B specifies a storage area (memory transistor) in which error-free initial setting data A is stored. FIG. 11 shows an example where the address B specifies, for example, the memory transistors MTr6 arranged along the word-line WL6. According to the address B, the fourth embodiment starts the read operation of the initial setting data A from the storage area (memory transistor) in which error-free initial setting data A is stored. The fourth embodiment may thus reduce the number of times of reading the initial setting data A. Note that with the above operation, the fourth embodiment may also exert an advantage similar to that in the first embodiment.

Referring now to FIG. 12, the read operation of the initial setting data A according to the fourth embodiment will be described in more detail. First, according to the address B, the control circuit 205 specifies the memory transistor MTr from which the read operation of the initial setting data A is started (S101). FIG. 11 shows an example where the memory transistors MTr8 arranged along the word-line WL8 are first specified.

After step S101, the control circuit 205 reads the initial setting data A from the memory transistor MTr specified in step S101 (S102). The control circuit 205 then determines whether the initial setting data A includes an error (S103). Here, if the initial setting data A includes an error (Yes in S103), then the control circuit 205 changes the memory transistor MTr from which the initial setting data A is read (S104), and performs step S102 again. FIG. 11 shows an example where an error is detected in the initial setting data A in the memory transistors MTr8, and thus instead of the memory transistors MTr8, the memory transistors MTr7 are used for reading the initial setting data A again. Additionally, FIG. 11 shows an example where an error is detected in the initial setting data A in the memory transistors MTr7, and thus instead of the memory transistors MTr7, the memory transistors MTr6 are used for reading the initial setting data A again.

In contrast, if the initial setting data A is correct (No in S103), the control circuit 205 updates the address B (S105) and ends the read operation of the initial setting data A. FIG. 11 shows an example where no error is detected in the initial setting data A read from the memory transistors MTr6, and thus the address of the memory transistor MTr6 is stored in the memory transistors MTr9 as the address B. Therefore, when the initial setting data A is read again, reading of the initial setting data A from the memory transistor MTr6 is started according to the address B.

### Fifth Embodiment

A non-volatile memory system according to a fifth embodiment will be described. The configuration of the fifth embodiment is similar to that of the first embodiment and thus its description is omitted here. As described below, the read operation of the initial setting data A in the fifth embodiment is different from that in the first embodiment.

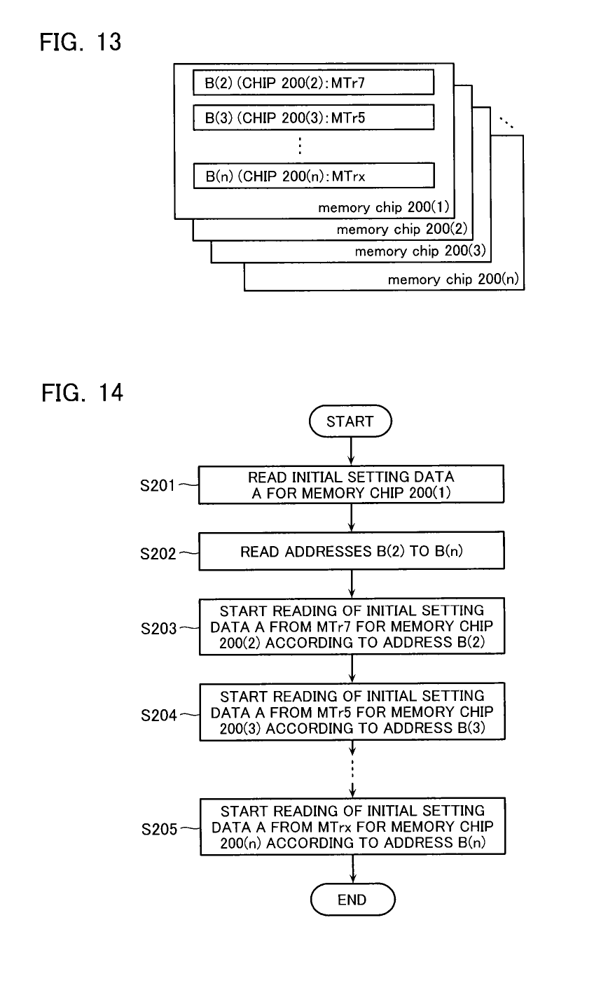

First, referring to FIG. 13, memory chips 200(1) to 200(n) according to the fifth embodiment will be described. As described above, each of the memory chips 200(1) to 200(n) includes a memory cell array 201. In the fifth embodiment, the initial setting data A is read in the order of the memory chips 200(1), 200(2), 200(3), . . . . Further, for each of the memory chips 200(1) to 200(n), the initial setting data A is read in the order of the memory transistors MTr8, MTr7, MTr6, . . . . If, however, the read operation is started from the memory transistor MTr8 in all memory chips 200(1) to 200(n) every time the initial setting data A is read, a large number of readings are performed.

In the fifth embodiment, therefore, the memory cell array 201 in the memory chip 200(1) has addresses B(2) to B(n) as shown in FIG. 13. Each of the addresses B(2) to B(n) specifies storage areas (memory transistors) in the memory chips 200(2) to 200(n) in which error-free initial setting data A is stored. FIG. 13 shows an example where the address B(2) specifies the memory transistor MTr7 in the memory chip 200(2), while the address B(3) specifies the memory transistor MTr5 in the memory chip 200(3). According to the addresses B(2) to B(n), the fifth embodiment starts the read operation of the initial setting data A from the storage areas (memory transistors) in the memory chips 200(2) to 200(n) in which error-free initial setting data A is stored. The fifth embodiment may thus reduce the number of times of reading the initial setting data A. Note that with the above operation, the fifth embodiment may also exert an advantage similar to that in the first embodiment.

Referring now to FIG. 14, the read operation of the initial setting data A performed for the memory chips 200(1) to 200(n) will be described in more detail. With reference to FIG. 14, first, the control circuit 205 reads the initial setting data A for the memory chip 200(1) (S201). Then, the control circuit 205 reads the addresses B(2) to B(n) from the memory chip 200(1) (S202).

Then, according to the address B (2), the control circuit 205 starts reading of the initial setting data A from the memory transistor MTr7 for the memory chip 200(2) (S203). After the reading of the initial setting data A is completed for the memory chip 200(2), the control circuit 205 starts, according to the address B(3), reading of the initial setting data A from the memory transistor MTr5 for the memory chip 200(3) (S204). Subsequently after the reading of the initial setting data A is completed for the memory chip 200(3), the same process is repeated until the reading of the initial setting data A for the memory chip 200(n) (S205).

### [Others]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

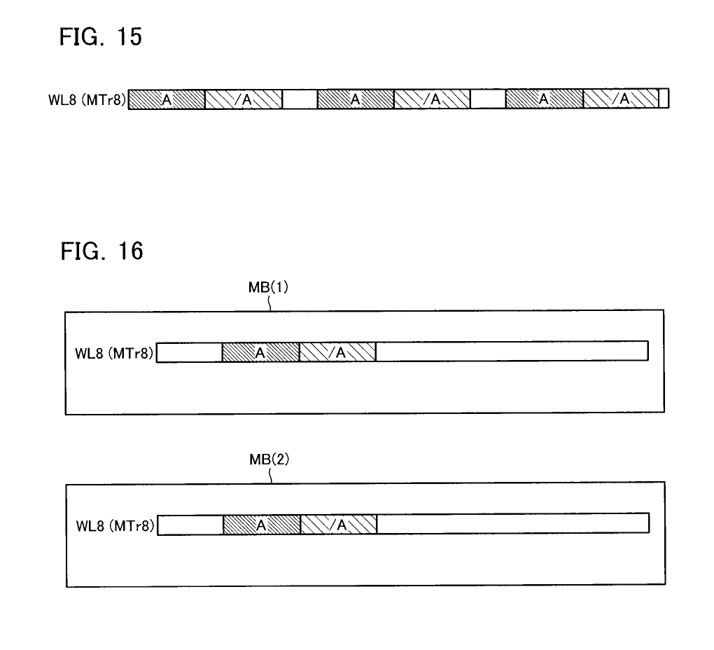

For example, a plurality of initial setting data sets A and inverted data sets /A may be stored in the memory transistors MTr8, as the storage areas, arranged along one word-line WL8, as shown in FIG. 15. Further, a plurality of initial setting data sets A and inverted data sets /A may be stored in the memory transistors MTr8, as the storage areas, arranged along the word-line WL8 in the different memory blocks MB(1) and MB(2), as shown in FIG. 16.

Further, the initial setting data A and inverted data /A may be stored only in the memory transistors MTr arranged along the odd-numbered word-lines WL or the even-numbered word-lines WL.

Further, in the first embodiment, the read scheme may be changed depending on the address Add.

Further, although each of the above embodiments illustrates a stacked NAND flash memory, it should be understood that the present invention is applicable to a normal NAND flash memory having no three-dimensional structure.

What is claimed is:

1. A non-volatile semiconductor memory device comprising:
a memory cell array comprising a plurality of memory cells, and storing initial setting data in each of a plurality of storage areas; and
a control circuit configured to read the initial setting data from the storage areas,
the control circuit being configured to read, when the control circuit detects an error in the initial setting data read from one of the storage areas, initial setting data from another storage area.

2. The non-volatile semiconductor memory device according to claim 1, wherein
the control circuit is configured to receive, when the control circuit detects an error in the initial setting data read from one of the storage areas, a first address and reads initial setting data from another storage area corresponding to the first address.

3. The non-volatile semiconductor memory device according to claim 1, wherein
the control circuit is configured to count the number of times of reading the initial setting data, and depending on the number of times of reading the initial setting data, change the storage area from which the initial setting data is read and a scheme whereby the initial setting data is read.

4. The non-volatile semiconductor memory device according to claim 1, wherein
the control circuit is configured to receive a command for performing reading of the initial setting data, and in response to one command, read the initial setting data from a different storage area every time an error is detected in the initial setting data.

5. The non-volatile semiconductor memory device according to claim 1, wherein
the memory cell array is configured to store a second address corresponding to a storage area storing error-free initial setting data, and
the control circuit is configured to read the initial setting data from the storage area storing the error-free initial setting data according to the second address.

6. The non-volatile semiconductor memory device according to claim 1, comprising:
a first memory chip having the memory cell array; and
a second memory chip having the memory cell array, the second memory chip storing a third address corresponding to a storage area storing error-free initial setting data in the first memory chip, wherein
the control circuit is configured to read the initial setting data and the third address in the second memory chip, and
the control circuit is configured to read the initial setting data from the storage area storing the error-free initial setting data in the first memory chip according to the third address.

7. The non-volatile semiconductor memory device according to claim 1, wherein
the memory cell array comprises:
a first semiconductor layer extending in a direction perpendicular to a substrate, and functioning as a body of the memory cell;
a charge accumulation layer provided on a side surface of the first semiconductor layer, and accumulating charge; and
a first conductive layer sandwiching the charge accumulation layer with the first semiconductor layer, and functioning as gates of the memory cells.

8. The non-volatile semiconductor memory device according to claim 1, wherein
the memory cell array stores inverted data of the initial setting data in each of the storage areas, and
the control circuit detects an error in the initial setting data according to the inverted data.

9. The non-volatile semiconductor memory device according to claim 1, wherein
the memory cell array further comprises a plurality of word-lines commonly connecting gates of a plurality of memory cells, and
each of the initial setting data sets is stored in the storage areas arranged along each word-line.

10. The non-volatile semiconductor memory device according to claim 1, wherein
the memory cell array further comprises a plurality of word-lines commonly connecting gates of a plurality of memory cells, and
the initial setting data sets are stored in the storage areas arranged along one of the word-lines.

11. The non-volatile semiconductor memory device according to claim 1, wherein
the memory cell array comprises a plurality of memory blocks each providing a minimum erase unit that is collectively erased in a data erase operation, and
the initial setting data is stored in the storage areas in the memory blocks.

12. The non-volatile semiconductor memory device according to claim 1, wherein
the memory cell array further comprises:
a memory string comprising a plurality of memory cells connected in series;
a first select transistor connected to a first end of the memory string; and
a second select transistor connected to a second end of the memory string,
the first select transistor comprises:
a first semiconductor layer extending in a direction perpendicular to a substrate, and functioning as a body of the first select transistor;
a first gate insulating layer provided on a side surface of the first semiconductor layer; and
a first conductive layer sandwiching the first gate insulating layer with the first semiconductor layer, and functioning as a gate of the first select transistor,
the second select transistor comprises:
a second semiconductor layer extending in a direction perpendicular to the substrate, and functioning as a body of the second select transistor;
a second gate insulating layer provided on a side surface of the second semiconductor layer; and
a second conductive layer sandwiching the second gate insulating layer with the second semiconductor layer, and functioning as a gate of the second select transistor.

13. A method of reading data from a non-volatile semiconductor memory device, the non-volatile semiconductor memory device comprising a memory cell array comprising a plurality of memory cells and storing initial setting data in each of a plurality of storage areas,
the method comprising reading, when an error is detected in the initial setting data read from one of the storage areas, initial setting data from another storage area.

14. The method of reading data from a non-volatile semiconductor memory device according to claim 13, further comprising receiving, when an error is detected in the initial setting data read from one of the storage areas, a first address, and reading initial setting data from another storage area corresponding to the first address.

15. The method of reading data from a non-volatile semiconductor memory device according to claim 13, further comprising counting the number of times of reading the initial setting data, and depending on the number of times of reading the initial setting data, changing the storage area from which the initial setting data is read and a scheme whereby the initial setting data is read.

16. The method of reading data from a non-volatile semiconductor memory device according to claim 13, further comprising receiving a command for performing reading of the initial setting data, and in response to one command, reading the initial setting data from a different storage area every time an error is detected in the initial setting data.

17. The method of reading data from a non-volatile semiconductor memory device according to claim 13, further comprising causing the memory cell array to store a second address corresponding to a storage area storing error-free initial setting data, and reading the initial setting data from the storage area storing the error-free initial setting data according to the second address.

18. The method of reading data from a non-volatile semiconductor memory device according to claim 13, wherein
the non-volatile semiconductor memory device further comprises:
a first memory chip having the memory cell array; and
a second memory chip having the memory cell array, the second memory chip storing a third address corresponding to a storage area storing error-free initial setting data in the first memory chip,
the method further comprises reading the initial setting data and the third address in the second memory chip, and reading the initial setting data from the storage area storing the error-free initial setting data in the first memory chip according to the third address.
